(19) United States
(12) Patent Application Publication
(10) Pub. No.: US 2023/0245988 A1
(43) Pub. Date: Aug. 3, 2023

(54) Harvested Reconstitution Bumping

(71) Applicant: Apple Inc., Cupertino, CA (US)

(72) Inventors: Kwan-Yu Lai, Campbell, CA (US); Kunzhong Hu, Cupertino, CA (US); Jun Zhai, Cupertino, CA (US); Young Doo Jeon, San Jose, CA (US)

(21) Appl. No.: 18/058,006

(22) Filed: Nov. 22, 2022

Related U.S. Application Data
(60) Provisional application No. 63/304,535, filed on Jan. 28, 2022.

(51) Int. Cl. H01L 23/00

(52) U.S. Cl. CPC H01L 24/11; H01L 24/73; H01L 24/13; H01L 24/20; H01L 24/19; H01L 24/14; H01L 2224/73101; H01L 2224/2101; H01L 2224/2105; H01L 2224/211; H01L 2224/214; H01L 2224/19; H01L 2224/11002; H01L 2224/11916; H01L 2224/11462; H01L 2224/11849; H01L 2224/1184; H01L 2224/14131; H01L 2224/14133; H01L 2224/13005; H01L 2224/13014; H01L 2224/13018; H01L 2224/13075; H01L 2224/13541; H01L 2224/13552; H01L 2224/13575; H01L 2924/35121

(57) ABSTRACT

Die reconstitution methods and dies with reconstituted contact bumps are described. In an embodiment, a die reconstitution method includes reconstituting a plurality of dies including first contact bumps of a first type, partially removing the first contact bumps, and forming second contact bumps of a second type on top of the partially removed first contact bumps, where the second type is different than the first type.

### RELATED APPLICATIONS

This application claims the benefit of priority of U.S. Provisional Application No. 63/304,535 filed Jan. 28, 2022, which is incorporated herein by reference.

### BACKGROUND

### Field

Embodiments described herein relate to microelectronic chip manufacture, and more particularly to wafer level bumping.

### Background Information

Microelectronic chip manufacture includes well-established wafer level processing sequences which commonly commence with a silicon wafer, followed by die preparation and bumping at the wafer scale, concluding with die singulation from the silicon wafer. There are a variety of ways to perform wafer bumping, with most conventional methods including electrochemical deposition, electroplating, stencil printing, etc. Selection of a various bumping technique may depend upon a variety of factors, including downstream application for the die and type of package integration.

One type of bump is the controlled collapsed chip connection (C4) bump. The C4 bump may be fabricated by application of a solder material into photoresist mask openings, followed by stripping of the photoresist and reflow. This may result in smooth truncated spherical C4 bumps due to surface tension. Another type of bump is the chip connection (C2) bump, where a solder can be applied to the top surface of a metal stud, or pillar, that is exposed within a photoresists layer. The photoresist layer can subsequently be stripped, optionally followed by reflow. Since the solder volume is less than with C4 bumps, the solder may form a cap (or tip) on top of the metal stud.

### BRIEF DESCRIPTION OF THE DRAWINGS

FIG. 1 a process flow for a method of harvesting dies with reconstituted bumps in accordance with embodiments.

FIGS. 2A-2F are schematic cross-sectional side view illustrations of a die and bump reconstitution process flow in accordance with an embodiment.

FIG. 2G is a schematic cross-sectional side view illustration of electronic package variations in accordance with embodiments.

FIG. 3A is a schematic cross-sectional side view illustration of C2-type contact bump prior to removal of a first passivation layer thickness in accordance with an embodiment.

FIG. 3B is a schematic cross-sectional side view illustration of C2-type contact bump after removal of a first passivation layer thickness in accordance with an embodiment.

FIG. 3C is a schematic cross-sectional side view illustration of a C2-type contact bump without a solder material in accordance with an embodiment.

FIG. 4 is a schematic cross-sectional side view illustration after removing a thickness of a C2-type contact bump in a bump reconstitution flow in accordance with an embodiment.

FIG. 5A is a schematic cross-sectional side view illustration after forming a C4-type contact bump over a partially removed C2-type contact bump in a bump reconstitution flow in accordance with an embodiment.

FIG. 5B is a schematic cross-sectional side view illustration after forming a C4-type contact bump over an RDL and partially removed C2-type contact bump in a bump reconstitution flow in accordance with an embodiment.

FIG. 6A is a schematic cross-sectional side view illustration of C2-type contact bump with integrated metal routing prior to removal of a first passivation layer thickness in accordance with an embodiment.

FIG. 6B is a schematic top view illustration of C2-type contact bump with integrated metal routing prior to removal of a first passivation layer thickness in accordance with an embodiment.

FIG. 7A is a schematic cross-sectional side view illustration after removing a thickness of a C2-type contact bump with integrated metal routing in a bump reconstitution flow in accordance with an embodiment.

FIG. 7B is a schematic top view illustration after removing a thickness of a C2-type contact bump with integrated metal routing in a bump reconstitution flow in accordance with an embodiment.

FIG. 8A is a schematic cross-sectional side view illustration after forming a C4-type contact bump over a partially removed C2-type contact bump with integrated routing in a bump reconstitution flow in accordance with an embodiment.

FIG. 8B is a top view illustration after forming a C4-type contact bump over a partially removed C2-type contact bump with integrated routing in a bump reconstitution flow in accordance with an embodiment.

FIG. 9A is a schematic cross-sectional side view illustration after forming an offset C4-type contact bump over a partially removed C2-type contact bump with integrated routing in a bump reconstitution flow in accordance with an embodiment.

FIG. 9B is a top view illustration after forming an offset C4-type contact bump over a partially removed C2-type contact bump with integrated routing in a bump reconstitution flow in accordance with an embodiment.

FIG. 10 is a schematic cross-sectional side view illustration of a C4-type contact bump in accordance with an embodiment.

FIG. 11 is a schematic cross-sectional side view illustration after removing a thickness of a C4-type contact bump in a bump reconstitution flow in accordance with an embodiment.

FIG. 12A is a schematic cross-sectional side view illustration after forming a C2-type contact bump over a partially removed C4-type contact bump in a bump reconstitution flow in accordance with an embodiment.

FIG. 12B is a schematic cross-sectional side view illustration after forming a C2-type contact bump over an RDL and partially removed C4-type contact bump in a bump reconstitution flow in accordance with an embodiment.

FIG. 13A is a schematic top view illustration of a harvested reconstitution bumping process with a scaled larger, coarser bump pitch in accordance with an embodiment.

FIG. 13B is a schematic top view illustration of a harvested reconstitution bumping process with a finer scaled bump pitch in accordance with an embodiment.

FIG. 13C is a schematic top view illustration of a harvested reconstitution bumping process with a finer scaled bump pitch and escape routing and unconnected underlying metal studs in accordance with an embodiment.

### DETAILED DESCRIPTION

Embodiments describe die reconstitution methods and reconstituted bump connections. In one aspect, it has been observed that electrical performance of dies on a given wafer is almost always a wide distribution. As a result, the manufacturer may bin the dies into different performance categories based on testing results, with not all binned dies being integrated into product. Furthermore, it has been observed that the same die architectures can be integrated into different products, though with different packaging requirements and bumping structures. Thus, the dies binned into different performance categories may not be fungible between different products.

In accordance with embodiments a die reconstitution method is described in which dies can be reconstituted for a secondary process flow and integration into a different product. For example, this may include binned dies that do not qualify for a primary process flow or excess dies from a primary process flow. As a result, multiple products can share the same yield buffer, increasing overall yield between multiple products while driving down cost and waste.

In an embodiment a die reconstitution method includes encapsulating a plurality of dies with a first molding compound on a carrier substrate. Each die may have already been tested, singulated and binned. Each die additionally includes a first group of first contact bumps of a first type. By way of example, this may be a C2-type or C4-type contact bump. The first groups of first contact bumps are then at least partially removed, for example with a grinding operation, followed by forming a second group of second contact bumps of a second type on top of the first group of first contact bumps. The plurality of dies now including the second group of second contact bumps of the second type is then singulated. Thus, the reconstitution method in accordance with embodiments forms composite contact bumps, including a second contact bump type on top of the original first contact bump type. Thus, dies with a C2-type contact bump can be reconstituted to include C4-type contact bumps built on top of the original C2-type contact bumps, and vice versa. It is to be appreciated that embodiments are not limited to C2-type and C4-type contact bumps, and the reconstitution method can be applied to different bumping technologies.

As used herein a C4-type contact bump means a bump structure including a reflowed solder on top of an underlying metal layer, which can be a metal stud. The reflowed solder may be a smooth truncated spherical, or half-sphere, shape due to surface tension. In some embodiments, the solder C4 bump thickness represents the majority of the thickness of the contact bump protruding away from (the top surface of) the underlying outermost passivation layer. As used herein C2-type contact bump means a contact bump structure including metal stud. The metal stud may be protruding from an underlying barrier layer or passivation layer (e.g. as a pillar), or may be partially or completely embedded within an encapsulation or passivation layer. Additionally, the C2-type contact bump may optionally include a solder tip. For example, for a C2-type contact bump the solder tip may represent a minority of the total thickness of the contact bump structure protruding from the underlying outermost passivation layer. Where no solder material is present the C2-type contact bump may be used for metal-metal bonding for example. A variety of C2-type contact bump embodiments are possible. For example, the metal stud of a C2-type contact bump can be co-planar with a top surface of an underlying barrier layer or passivation layer. For example, the metal stud can be embedded within an oxide layer for hybrid bonding.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer between layers may be directly in contact with the layers or may have one or more intervening layers.

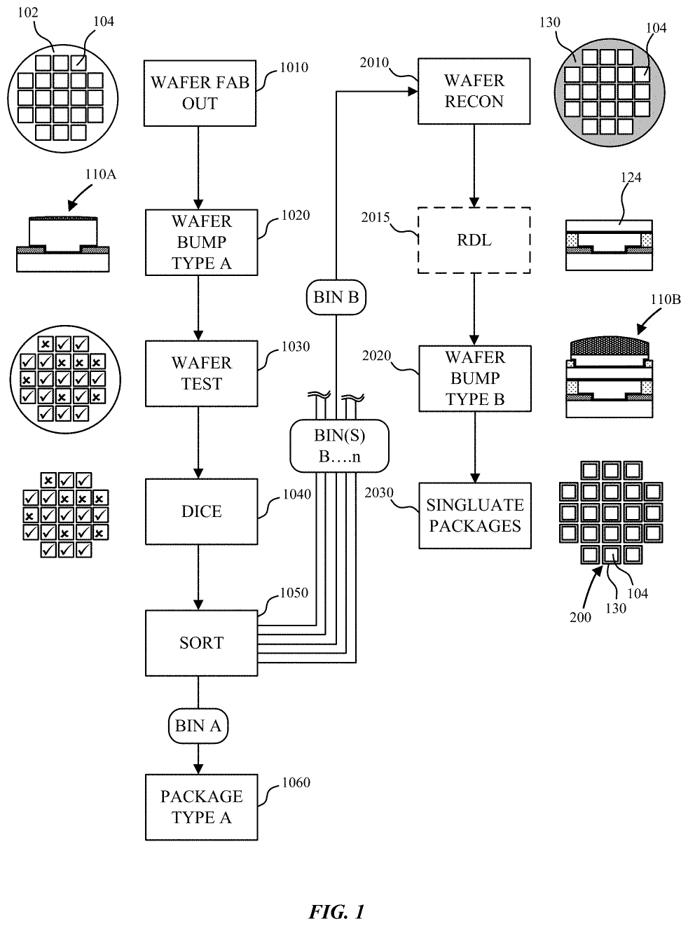

Referring now to FIG. 1 a process flow is illustrated for a method of harvesting dies with reconstituted bumps in accordance with embodiments. The process may begin at operation 1010 with a plurality of dies 104 fabricated in a wafer 102. At operation 1020 a plurality of first contact bumps 110A of a first type (type A) are formed over the dies 104. This may be followed by wafer testing at operation 1030 for electrical performance. For sake of convenience, this is illustrated as good dies (check mark) and bad dies (x mark), though data can be more comprehensive. In some fabrication sequences a top passivation layer can then be coated over the first contact bumps 110A after wafer testing, though this is not required. Dies 104, or die sets, can then be singulated at operation 1040.

The singulated dies 104 can then be sorted at operation 1050 into different bins, A, B, . . . n. For example, each different bin may correspond to a different process flow for reconstituted bumps.

Dies 104 in bin A can proceed to packaging at operation 1060, without further contact bump modification. Dies not moving to bin A, such as excess dies or dies not meeting electrical testing requirements for bin A can be processed with another bin B, etc.

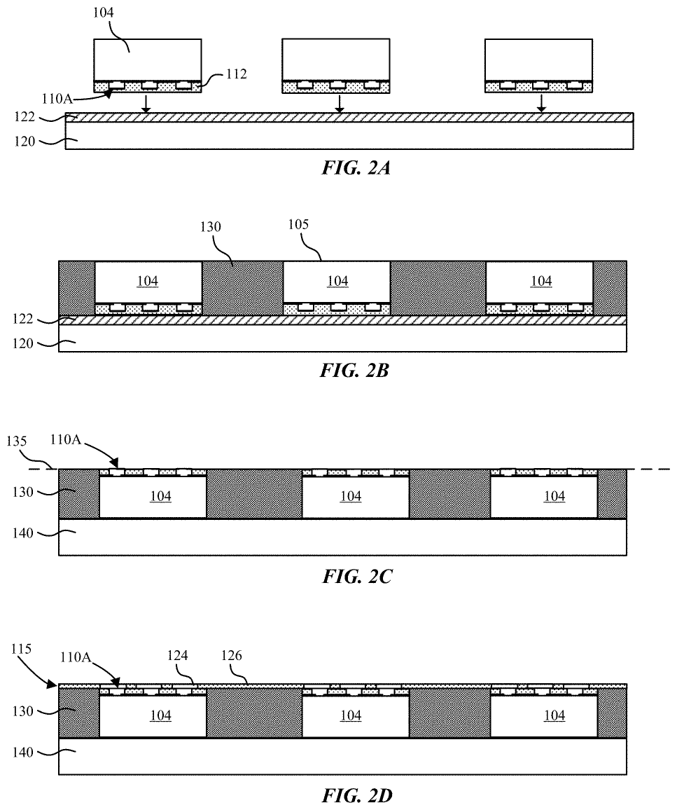

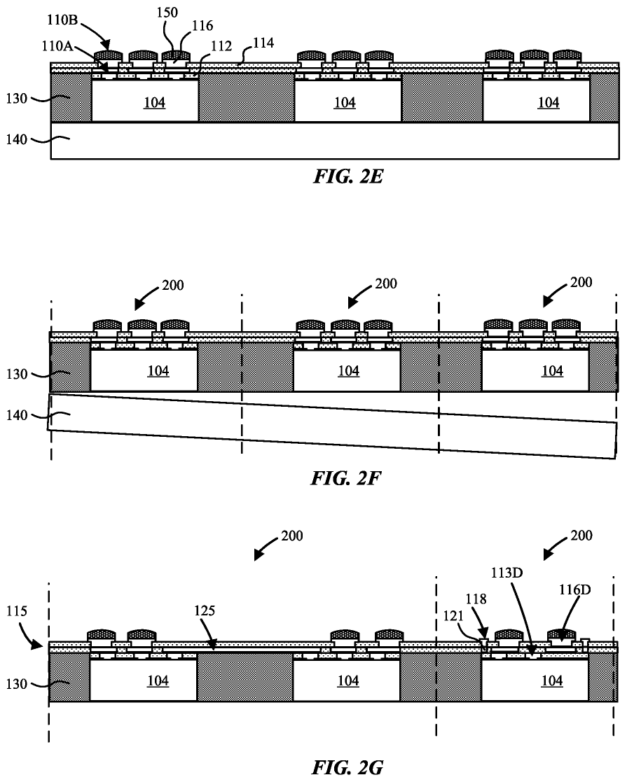

Still referring to FIG. 1, a reconstitution process flow for dies 104 in bin B is provided with operations 2010-2030. FIGS. 2A-2F are schematic cross-sectional side view illustrations of a die and bump reconstitution process flow in accordance with an embodiment. In interest of clarity and conciseness the detailed process flow in FIGS. 2A-2F is described concurrently with FIG. 1.

At operation 2010 a reconstituted wafer is formed with the dies 104 in bin B. The reconstitution flow can proceed in a face-down sequence (where dies are placed face down onto a carrier substrate) or face-up sequence (where dies are placed face up onto a carrier substrate). The particular embodiment illustrated in FIG. 2A shows a face-down sequence in which the dies 104, including first contact bumps 110A, are placed face-down onto a carrier substrate 120, such as a silicon wafer or other suitable substrate. More particularly, the dies 104 can be placed onto an adhesive layer 122 on the carrier substrate 120. It is to be appreciated that the first contact bumps 110A illustrated in FIG. 2A can be any type of bumps. In an embodiment, the first contact bumps 110A are C2-type contact bumps, and may be covered with a first passivation layer 112, which may be formed of a suitable material such as polymer (e.g. polyimide) or inorganic such as oxide or nitride.

The plurality of dies 104 can then be encapsulated in a molding compound layer 130 material, such as epoxy or other molding compound material, as shown in FIG. 2B. This may optionally be followed by a grinding operation to expose the back sides 105 of the dies. A second carrier substrate 140 can then be attached to the back sides 105 of the dies 104, followed by removal of the first carrier substrate 120 and adhesive layer 122. In accordance with embodiments, a grinding operation may then be performed to at least partially remove the first contact bumps 110A. This may result in a planarized surface 135 spanning portions of the first contact bumps 110A and the molding compound layer 130. It is to be appreciated a similar structure can also be obtained with a face-up sequence in which the dies are placed face-up, encapsulated with the encapsulation layer, followed by grinding.

At operation 2015 an optional redistribution layer (RDL) 115 including one or more wiring traces 124 and dielectric layers 126 can be formed. Dielectric layer(s) 126 may be formed of the same material as passivation layer 112, such as polyimide or inorganic, such as oxide, nitride, etc. The RDL 115 can be used for electrical distribution, including fan-in and fan-out routing, and may also be used to reduce mechanical stress in the resulting structure. For example, the subsequent second bump types can be misaligned over the first bump types, either by partially overlapping or not at all such that stress is redistributed. For example, the wiring traces 124 can provide a cantilever function between lower and top bump types.

At operation 2020 the second group of second contact bumps 110B of a second type (type B) is formed on top of the first group of first contact bumps 110A, and/or option RDL 115 if present. In the exemplary process flow illustrated, this can include deposition of a second passivation layer 114. The second passivation layer 114 may be similar to first passivation layer 112 and formed of a suitable material such as polyimide or inorganic. The second passivation layer 114 may be deposited over the entire reconstituted structure including the molding compound layer 130 and over the dies 104. Openings may be formed in the second passivation layer 114 to expose the thinned first metal studs, or planarized surface 135 thereof. In an embodiment an electroplating operation is then performed to form metal studs 116. Solder material can then be applied over the metal studs 116 and reflowed to form C4 bumps 150. For example, metal studs 116 and solder can be applied through openings in a photoresist layer, followed by stripping of the photoresist layer and reflow to form C4 bumps 150. Together, the metal studs 116 and C4 bumps for the second contact bumps 110B are on partially ground down first contact bumps 110A. At operation 2030 the dies 104 or die sets can then be singulated into electronic packages 200 (e.g. semiconductor chip packages) as shown in FIG. 2F, where the second carrier substrate 140 is also removed.

FIG. 2G is a schematic cross-sectional side view illustration of electronic package 200 variations in accordance with embodiments. As shown, the electronic packages 200 can be singulated to include one or more dies 104. In an embodiment, the electronic package 200 can include a die 104 set where one or more dies 104 are connected with die-to-die routing 125 within the RDL 115. The die-to-die routing 125 may be formed within the same metal layers as wiring traces 124. In accordance with embodiments, the die-to-die routing 125 can connect the first metal studs 113 of the dies 104. The die-to-die routing 125 may optionally be further connected to one or more second metal studs 116 (for outside electronic package connection), or not connected to a second metal stud 116 (so that the die-to-die routing is internal between dies 104 of the electronic package 200.

In an embodiment, one or more of the second contact bumps 110B include dummy second metal studs 116D, not electrically connected with the first metal studs 113. In an embodiment, one or more of the first metal studs are dummy first metal studs 113D, not electrically connected with the second metal studs 116 of the second contact bumps 110B. In some embodiments, the RDL 115 can include wiring traces 124 that can optionally facilitate electrical distribution, such as fan-in or fan-out routing of the second contact bumps 110B relative to the first contact bumps 110A. In an embodiment, RDL 115 can include a seal ring 118 formed of one or more metal filled vias or trenches 121. The seal ring 118 may provide additional mechanical stability and mitigate delamination of the multiple layers in the RDL 115. The seal ring 118 may optionally extend through passivation layer 114, or be buried beneath passivation layer 114. In accordance with embodiments, the original passivation layers 112 of dies 104 may protect the dies 104 from the environment and moisture ingress, removing constraints for materials selection of the dielectric layers of the RDL 115 and optionally passivation layer 114. Thus, the seal rings 118 may be formed more specifically for mechanical attributes.

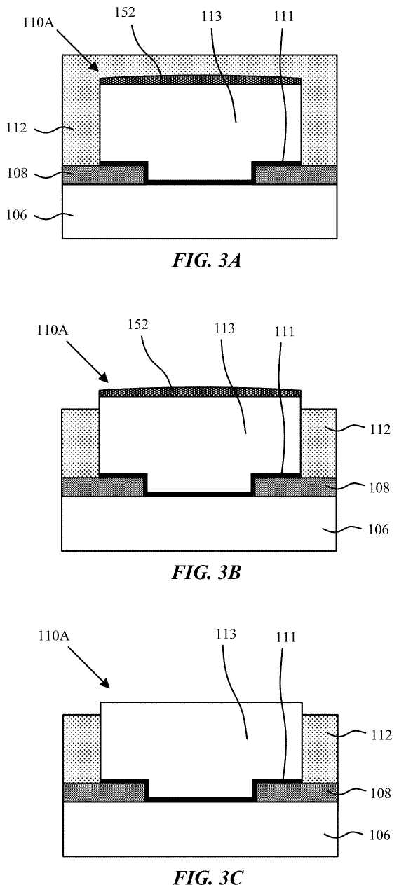

Referring now to FIG. 3A, a schematic cross-sectional side view illustration is provided of C2-type contact bump prior to removal of a first passivation layer thickness in accordance with an embodiment. In interest of consistency the C2-type contact bump of FIG. 3A is referred to as a first contact bump 110A since this is the first formed contact bump prior to reconstitution. In the illustrated embodiment, a barrier layer 108 is formed over a metal wiring layer 106 within a back-end-of-the-line (BEOL) build-up structure of the die. The barrier layer 108 may be formed of an inorganic material, such as silicon nitride for example. In accordance with embodiments, the first contact bump 110A may have been formed by deposition of a seed layer 111 (e.g. titanium) over the barrier layer 108 and within an opening in the barrier layer 108 exposing the underlying metal wiring layer 106. A photoresist layer can then be deposited and patterned to form an opening followed by electroplating of the first metal stud 113, such as copper. The top solder cap 152 can then optionally be formed over the first metal stud 113, followed by stripping of the photoresist layer and underlying seed layer 111. Following electrical testing, a first passivation layer 112 can be deposited, optionally covering the solder cap 152, if present, or partially covering the first metal stud 113.

Referring briefly again back to FIG. 1, following dicing, the processing of dies in bin A may proceed with the first contact bumps 110A. For example, the dies 104 can be reconstituted similarly as in FIGS. 2A-2B, followed by singulation of electronic packages. Prior to electronic package singulation, the first passivation layer 112, if present, can be etched back to expose the first contact bumps 110A as shown in FIGS. 3B-3C if the first contact bumps 110A are not already exposed.

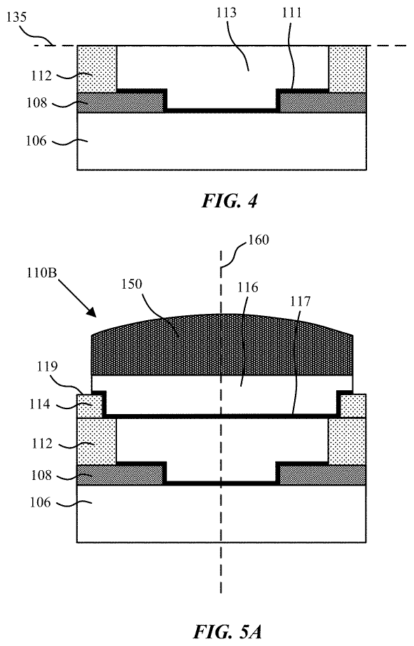

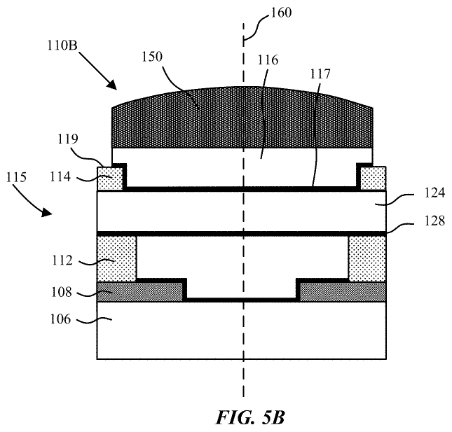

Dies 104 selected for reconstitution bumping however may proceed according to the sequence illustrated in FIGS. 2A-2F. FIG. 4 is a schematic cross-sectional side view illustration after removing a thickness of a C2-type contact bump in a bump reconstitution flow in accordance with an embodiment. As shown, a grinding operation may be performed to remove the solder caps 152, if present, and partial thicknesses of the first metal studs 113, leaving behind a planarized surface 135 formed of the first passivation layer 112 and first metal studs 113. Second contact bumps 110B may then be formed on the partially removed first contact bumps 110A as shown in FIG. 5A. In particular, FIG. 5A illustrates the formation of a C4-type contact bump over a partially removed C2-type contact bump. In such a processing sequence, a second passivation layer 114 can be formed over the planarized surface 135, followed by patterning to form an opening. A second seed layer (e.g. titanium) is then deposited over the second passivation layer 114 and within the opening on the exposed planarized surface of the first metal stud 113. A photoresist layer may then be deposited and patterned to form an opening followed by electroplating a second metal stud 116, such as copper, within the photoresist opening. This may be followed by application of a solder material into an overlying volume of the photoresist opening. The photoresist and underlying seed layer 117 portions can then be stripped, followed by reflow to form the C4 bumps 150.

In the illustrated embodiments the second contact bumps 110B are formed directly on the partially removed first contact bumps 110A during the bump reconstitution processes. In this manner, the second metal stud 116 is stacked directly onto top of the first metal stud 113 and intervening seed layer 117. This may allow the second metal stud 116 to be thinner than if formed separately by itself In an alternative arrangement illustrated in FIG. 5B, a redistribution layer (RDL) 115 can be formed after the grinding operation illustrated in FIG. 4 to provide additional routing on the first metal stud 113 prior to forming the second contact bump 110B. The RDL may include for example, deposition and patterning of a dielectric layer 126 (FIG. 2D), followed by deposition of one or more seed and/or barrier layer 128 (e.g. Ti/Ta/TaN) and wiring trace 124, which may be a metal such as copper.

In the particular embodiments illustrated in FIGS. 5A-5B, the metal studs 116 of the second contact bumps 110B are aligned over the metal studs 113 of the first contact bumps 110A, with substantially aligned center points 160 (or centroids). In accordance with embodiments, the metal studs 116 of the second contact bumps 110B can be offset with the metal studs 113 of the first contact bumps 110A, for example with a half bump width (e.g. measured by maximum width of the second metal studs 116), full bump width, or more. The larger offsets can be achieved using the RDL 115. In accordance with embodiments, some offset may mitigate mechanical stress, for example in a cantilever action where stress created during attachment/bumping is not directly transferred through the metal layers of the stacked contact bumps.

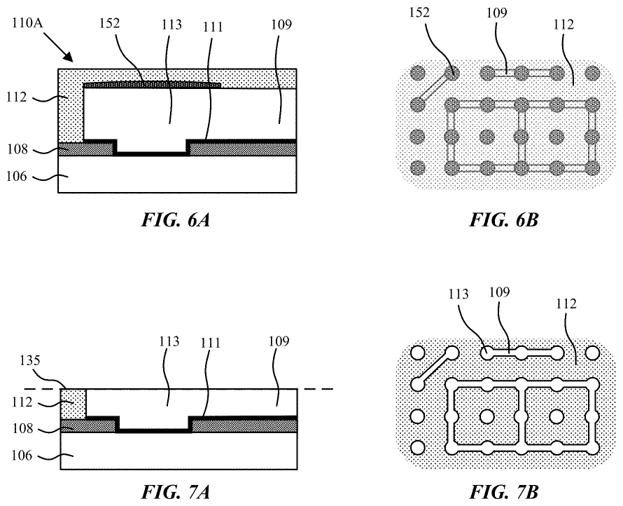

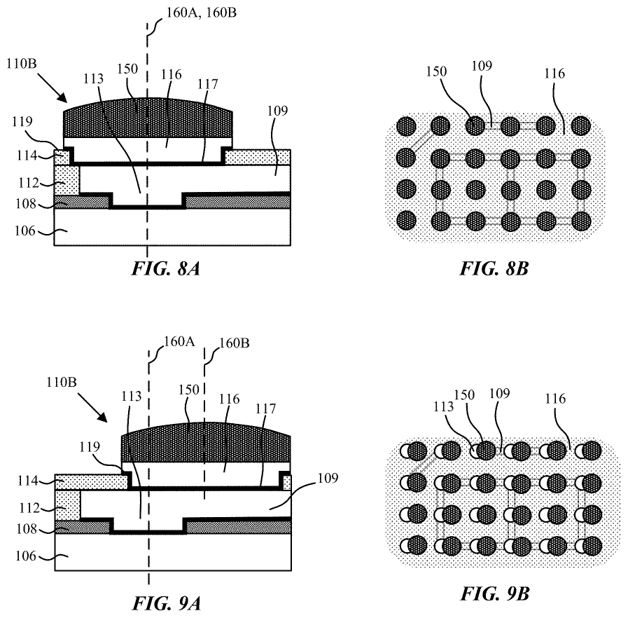

Routing can also be integrated with the first contact bumps 110A. FIGS. 6A and 6B are schematic cross-sectional side view and top view illustrations of C2-type contact bump with integrated metal routing prior to removal of a first passivation layer thickness in accordance with an embodiment. The first contact bump 110A illustrated in FIGS. 6A-6B is similar to that illustrated in FIG. 3A with the addition of a routing line 109 integrally formed with the first metal stud 113. FIGS. 7A-7B illustrate the structure of FIGS. 6A-6B following the grinding operation, similar to FIG. 4. As shown, following the grinding operation, the routing lines 109 are exposed along the planarized surface 135. FIGS. 8A-8B illustrated the structure of FIGS. 7A-7B following the formation of the second contact bumps 110B on top of the partially removed first contact bumps 110A similar to FIG. 5A. As shown, the routing lines 109 are now buried underneath the second passivation layer 114.

Referring to both FIG. 5A and FIG. 8A in accordance with the embodiments, the size of the second contacts bumps 110B (e.g. C4-type) can be decoupled from the critical dimension of the first contact bumps 110A (e.g. C2-type). Furthermore, it is possible to locate the second contact bumps 110B over routing lines 109, or for the second contact bumps 110B to be unlanded (e.g. partially overlapping) the first contact bumps 110A. Second contact bumps 110B may also be misaligned by a full bump width (as measured by the second contact bumps 110B maximum width) or more.

Still referring to both FIG. 5A and FIG. 8A, in an embodiment a composite contact bump structure includes a metal wiring layer 106, a first metal stud 113 on the metal wiring layer 106 and laterally surrounded by a first passivation layer 112. A planarized surface 135 spans (or is formed of) the first passivation layer 112 and the first metal stud 113 (and optionally routing lines 109). A second passivation layer 114 is formed on the first passivation layer 112 and over the first metal stud 113. A seed layer 117 is formed on the second passivation layer 114 and within the opening in the second passivation layer and on the first metal stud 113. A second metal stud 116 is formed within the opening in the second passivation layer 114. As shown, the second metal stud 116 can also be located over a portion of the second passivation layer 114. In accordance with embodiments a solder material is located on top of the second metal stud 116. In the particular embodiment illustrated, the solder material is a C4 bump 150 on top of the second metal stud. Furthermore, the C4 bump 150 can be thicker than a thickness of the second metal stud 116 protruding away from (the top surface 119 of) the second passivation layer 114.

The second metal studs 116 in accordance with embodiments may be wider or narrower than the first metal studs 113. In an exemplary embodiment, the second metal studs 116 for a C4-type contact bump may be wider than the first metal studs 113. The first metal studs 113 and second metal studs 116 may also be formed of the same material, such as copper. In the embodiment illustrated in FIGS. 8A-8B, a routing line 109 can be integrally formed with the first metal stud 113. The routing line(s) 109 can connect with one another and between multiple first metal studs 113 and second metal studs 116. Furthermore, the routing line(s) can be covered by the second passivation layer 114. The opening in the second passivation layer 114 within which the second metal stud 116 is formed may also be aligned with the center point 160B of the second metal stud 116. Likewise, the opening in the first passivation layer 112 within which the first metal stud 113 is formed may be aligned with the center point 160A of the first metal stud 113. As shown in FIGS. 9A-9B, the integrated routing lines 109 can provide additional electrical routing, and may optionally be utilized for partial or full contact bump offset, similarly as with an RDL.

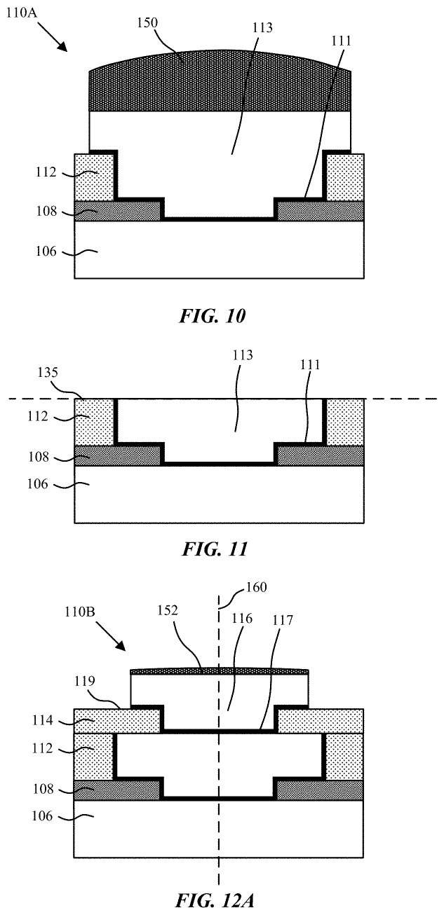

Up until this point the process flows and illustrations have been provided with regard to the second contact bump 110B being a C4-type contact bump formed over a C2-type first contact bump 110A. However, embodiments are not limited to this particular arrangement and may include a variety of different types of contact bumps. Furthermore, embodiments may include a C2-type second contact bump 110B over a C4-type first contact bump 110A. Such a process flow is illustrated in FIGS. 10-12B.

FIG. 10 is a schematic cross-sectional side view illustration of a C4-type contact bump in accordance with an embodiment. Similar to previous descriptions, the original wafer 102 may include a plurality of first contact bumps 110A of a first type (e.g. C4-type). In such an embodiment, the first metal studs 113 (e.g. copper) are plated onto seed layer 111 formed over the first passivation layer 112 and within openings in the first passivation layer 112 and barrier layer 108 exposing metal wiring layer 106. The first metal stud 113 may be formed as previously described using a patterned photoresist. This can be followed by deposition of a solder material within the opening in the patterned photoresist, stripping the photoresist and underlying seed layer 111, followed by reflow of the C4 bump 150.

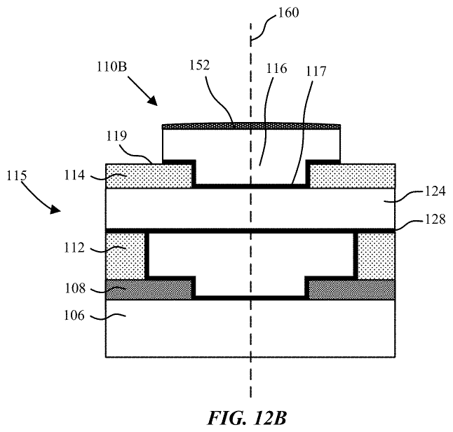

FIG. 11 is a schematic cross-sectional side view illustration after removing a thickness of a C4-type contact bump in a bump reconstitution flow in accordance with an embodiment. In accordance with embodiments, this may be accomplished using a grinding operation as previously described resulting in a planarized surface spanning the first metal stud 113 and first passivation layer 112. Referring now to FIG. 12A, a C2-type second contact bump 110B is formed over the partially removed first contact bump 110A. This may be accomplished by depositing the second passivation layer 114, forming an opening in the second passivation layer, depositing the second seed layer 117, followed by formation of a patterned photoresist layer and plating the second metal stud 116 within the opening in the photoresist layer. A solder cap 152 can then optionally be applied over the second metal stud 116 followed by stripping of the photoresist layer and any underlying seed layer 117. A solder cap 152 may not be formed in some embodiments.

Still referring FIG. 12A, in an embodiment a composite contact bump structure includes a metal wiring layer 106, a first metal stud 113 on the metal wiring layer 106 and laterally surrounded by a first passivation layer 112. A planarized surface 135 spans (or is formed of) the first passivation layer 112 and the first metal stud 113. A second passivation layer 114 is formed on the first passivation layer 112 and over the first metal stud 113. A seed layer 117 is formed on the second passivation layer 114 and within the opening in the second passivation layer and on the first metal stud 113. A second metal stud 116 is formed within the opening in the second passivation layer 114. As shown, the second metal stud 116 can also be located over a portion of the second passivation layer 114. In accordance with embodiments a solder material can optionally be located on top of the second metal stud 116. In the particular embodiment illustrated, the solder material is a solder cap 152 on top of the second metal stud. Furthermore, the solder cap 152 can be thinner than a thickness of the second metal stud 116 protruding away from (the top surface 119 of) the second passivation layer 114.

The second metal studs 116 in accordance with embodiments may be wider or narrower than the first metal studs 113. In an exemplary embodiment, the second metal studs 116 for a C2-type contact bump may be narrower than the first metal studs 113. The first metal studs 113 and second metal studs 116 may also be formed of the same material, such as copper.

In the embodiment illustrated in FIG. 12B, an RDL 115 can optionally be formed prior to formation of the second contact bumps 110B, similarly as previously described with regard to FIG. 5B. In the particular embodiments illustrated in FIG. 12A-12B, the second metal studs 116 are aligned over the first metal studs 113, with substantially aligned center points 160 (or centroids). These may correspond to the openings within the passivation layers 112, 114. In accordance with embodiments, the second metal studs 116 can be offset with the first metal studs 113, for example with a half bump width, full bump width, or more. The larger offsets can be achieved using the RDL 115 of FIG. 12B. In accordance with embodiments, some offset may mitigate mechanical stress, for example in a cantilever action where stress created during attachment/bumping is not directly transferred through the metal layers of the stacked contact bumps.

Referring again to FIG. 2G the various contact bump structures in accordance with embodiments described up until this point can be combined with the package variations illustrated in FIG. 2G. In an embodiment, an electronic package 200 includes a first die 104 embedded in a molding compound layer 130. The first die 104 includes a metal wiring layer 106, a first metal stud 113 formed on the metal wiring layer and laterally surrounded by a first passivation layer 112, and a planarized surface 135 spanning the first passivation layer 112 and the first metal stud 113 and the molding compound layer 130. A second passivation layer 114 is formed over the first passivation layer 112 and spans over the molding compound layer 130. The second passivation layer 114 may be directly on the first passivation layer 112 and molding compound layer 130 or may be separated by additional layer(s). An opening is located in the second passivation layer 114, and a seed layer 117 is formed within the opening and over the first metal stud 113. A second metal stud 116 is then formed on the seed layer within the opening of the second passivation layer 114. In accordance with embodiments, the second metal stud 116 and opening in the second passivation layer 114 can be aligned with the first metal stud 113, and directly over the first metal stud 113, or may be partially or fully offset from the first metal stud 113 such that the second metal stud 116 and opening in the second passivation layer 114 are partially directly over the first metal stud 113, or not directly over the first metal stud 113.

In an embodiment, the electronic package 200 includes a dummy second metal stud 116D over the first die, where the dummy second metal stud 116D is not electrically connected to the first die 104. In an embodiment, a second die 104 is embedded within the molding compound layer 130, and an RDL 115 spans over the first die 104, the second die 104, and the molding compound layer 130. The RDL 115 may include die-to-die routing 125 connecting another metal stud (e.g. another first metal stud 113) on the metal wiring layer 106 of the first die to the second die 104 (e.g. to another first metal stud 113 of the second die). The die-to-die routing 125 can be used exclusively for connection between one or more dies 104, and may optionally be further connected to a second metal stud 116 for external package connection. In an embodiment, the RDL 115 includes a seal ring 118 structure within the RDL 115.

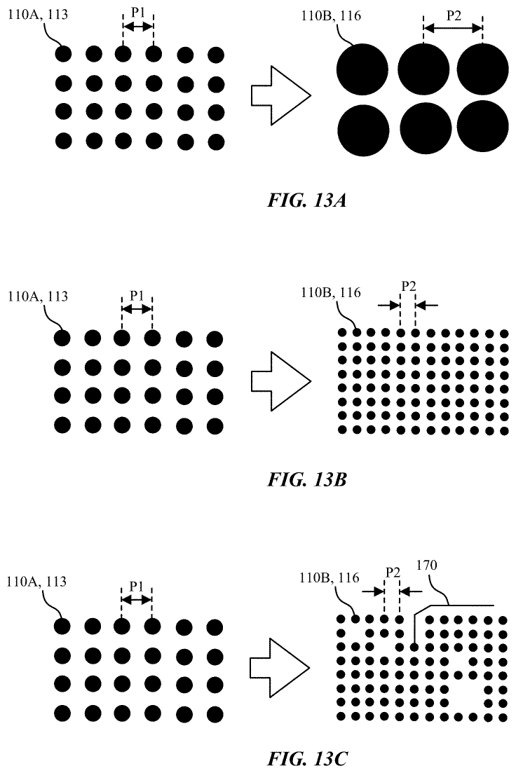

The pitch (P1) of the underlying first metal studs 113 and the pitch (P2) of the reconstituted second contact bumps 110B and second metal studs 116 do not necessarily have to match. In some embodiments, such as that illustrated in FIG. 13A neighboring second contact bumps 110B are merged into a larger, coarser pitch. For example, this may be to provide higher current carrying capability and power delivery. The larger pitch does not necessarily have to be integer multiples of the original first metal studs 113. In other embodiments, such as that illustrated in FIG. 13B scaling down in pitch (split original bump/metal studs into smaller reconstituted pitch) could be true. Such a configuration may be utilized, for example, to create a uniform pitch for downstream fine pitch hybrid bonding process. By way of illustration, an exemplary pitch for C4-type bumps could range from 55 μm to 200 μm, and an exemplary pitch for C2-type bumps could range from 20 μm to 200 μm. Exemplary pitch for hybrid bonds could range from 2 μm to 50 μm for advanced xPU-xPU or xPU-memory interfaces. Referring to FIG. 13C, scaling down of the pitch in accordance with embodiments can additionally create escape routing 170 and/or cover up certain underlying first metal studs 113 (disable/disconnect) for security purposes using a harvested reconstitution bumping process. For example, the escape routing 170 can be formed in the same process and same metal layer as the second metal studs 116, and may span over the second passivation layer 114. Covering up certain underlying first metal studs 113 can additionally be achieved with larger pitch, or without changing pitch. Similarly, escape routing 170 is not necessarily dependent upon pitch.

In utilizing the various aspects of the embodiments, it would become apparent to one skilled in the art that combinations or variations of the above embodiments are possible for harvesting dies with reconstituted bumps. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A die reconstitution method comprising:
encapsulating a plurality of dies with a molding compound layer on a carrier substrate, wherein each die includes a first group of first contact bumps of a first type;
partially removing the first groups of first contact bumps;
forming a second group of second contact bumps of a second type on top of the first group of first contact bumps, wherein the first type is different than the second type; and
singulating the plurality of dies with the second group of second contact bumps of the second type.

2. The die reconstitution method of claim 1, wherein the first type is a chip connection type (C2-type) bump and the second type is a controlled collapsed chip connection type (C4-type) bump.

3. The die reconstitution method of claim 1, wherein the first type is a controlled collapsed chip connection type (C4-type) bump and the second type is a chip connection type (C2-type) bump.

4. The die reconstitution method of claim 1, wherein partially removing the first groups of first contact bumps comprises grinding the first groups of first contact bumps to reduce a thickness of a first metal stud for each first contact bump.

5. A composite contact bump structure comprising:
a metal wiring layer;
a first metal stud on the metal wiring layer and laterally surrounded by a first passivation layer;
a planarized surface spanning the first passivation layer and the first metal stud;
a second passivation layer over the first passivation layer;
an opening in the second passivation layer;
a seed layer on the second passivation layer, within the opening in the second passivation layer and over the first metal stud; and
a second metal stud on the seed layer within the opening in the second passivation layer.

6. The composite contact bump structure of claim 5, further comprising a solder material on top of the second metal stud.

7. The composite contact bump structure of claim 6, wherein the solder material is a C4 bump on top of the second metal stud.

8. The composite contact bump structure of claim 7, wherein the C4 bump is thicker than a thickness of the second metal stud protruding away from the second passivation layer.

9. The composite contact bump structure of claim 7, wherein the second metal stud is wider than the first metal stud.

10. The composite contact bump structure of claim 6, wherein the solder material is solder cap on top of the second metal stud.

11. The composite contact bump structure of claim 10, wherein the solder cap is thinner than a thickness of the second metal stud protruding away from the second passivation layer.

12. The composite contact bump structure of claim 10, wherein the second metal stud is narrower than the first metal stud.

13. The composite contact bump structure of claim 5, wherein the second metal stud is narrower than the first metal stud.

14. The composite contact bump structure of claim 13, wherein the second metal stud protrudes away from the second passivation layer.

15. The composite contact bump structure of claim 5, wherein the second metal stud protrudes away from the second passivation layer.

16. The composite contact bump structure of claim 5, wherein the second metal stud and the first metal stud are formed of a same metal.

17. The composite contact bump structure of claim 5, wherein a center point of the second metal stud is aligned with a center point of the first metal stud.

18. The composite contact bump structure of claim 5, wherein a center point of the second metal stud is offset from a center point of the first metal stud by at least a half maximum width of the second metal stud.

19. The composite contact bump structure of claim 5, further comprising a routing line integrally formed with the first metal stud.

20. The composite contact bump structure of claim 19, wherein the routing line connects to a second first metal stud.

21. The composite contact bump structure of claim 19, wherein the second passivation layer spans over the routing line.

22. The composite contact bump structure of claim 5, further comprising a redistribution layer between the first metal stud and the second metal stud.

23. The composite contact bump structure of claim 22, wherein the second metal stud is connected to the first metal stud through a wiring trace in the redistribution layer.

24. An electronic package comprising:
a first die embedded in a molding compound layer, the first die comprising:
a metal wiring layer;
a first metal stud on the metal wiring layer and laterally surrounded by a first passivation layer; and
a planarized surface spanning the first passivation layer, the first metal stud, and the molding compound layer;
a second passivation layer over the first passivation layer and spanning over the molding compound layer;
an opening in the second passivation layer;
a seed layer on the second passivation layer, within the opening in the second passivation layer and on the first metal stud; and
a second metal stud on the seed layer within the opening in the second passivation layer.

25. The electronic package of claim 24, further comprising a dummy second metal stud over the first die, wherein the dummy second metal stud is not electrically connected to the first die.

26. The electronic package of claim 24, further comprising a second die embedded within the molding compound layer, and a redistribution layer spanning over the first die, the second die, and the molding compound layer, wherein the redistribution layer includes a die-to-die routing connecting another metal stud on the metal wiring layer of the first die to the second die.

27. The electronic package of claim 24, further comprising a redistribution layer between the first metal stud and the second metal stud, and a seal ring structure within the redistribution layer.
